(19) United States
(12) Patent Application Publication
(10) Pub. No.: US 2018/0029944 A1
(43) Pub. Date: Feb. 1, 2018

(54) CERAMIC MATRIX COMPOSITE TURBINE COMPONENT WITH ENGINEERED SURFACE FEATURES RETAINING A THERMAL BARRIER COAT

(71) Applicant: SIEMENS AKTIENGESELLSCHAFT, München (DE)

(72) Inventors: Ramesh Subramanian, Oviedo, FL (US); Steffen Walter, Oberpframmern (DE); Niels Van der Laag, München (DE); Uwe Rettig, Ottobrunn (DE)

(21) Appl. No.: 15/550,118

(22) PCT Filed: Feb. 17, 2016
(86) PCT No.: PCT/US16/18224

§ 371 Date: Aug. 10, 2017

Related U.S. Application Data
(63) Continuation-in-part of application No. PCT/US2015/016318, filed on Feb. 18, 2015.
Application No. PCT/US2015/016318 is a continuation-in-part of application No. PCT/US2015/016331, filed on Feb. 18, 2015.

(51) Int. Cl. C04B 41/81; C23C 16/04; C04B 41/91; C23C 4/134

(52) U.S. Cl. CPC C04B 41/81; C23C 4/134; C23C 16/045; C04B 41/91; F01D 5/282

(57) ABSTRACT

An oxide and non-oxide based ceramic matrix composite (“CMC”) component for a combustion turbine engine has a solidified ceramic core with a three-dimensional preform of ceramic fibers, embedded therein. Engineered surface features (“ESFs”) are cut into an outer surface of the core and fibers of the preform. A thermal barrier coat (“TBC”) is applied over and coupled to the core outer surface and the ESFs. The ESFs provide increased surface area and mechanically interlock the TBC, improving adhesion between the ceramic core and the TBC.

### PRIORITY CLAIM

This application claims priority to International Application No. PCT/US15/16318, filed Feb. 18, 2015, and entitled “TURBINE COMPONENT THERMAL BARRIER COATING WITH CRACK ISOLATING ENGINEERED GROOVE FEATURES”; and International Application No. PCT/US15/16331, filed Feb. 18, 2015, and entitled “TURBINE COMPONENT THERMAL BARRIER COATING WITH CRACK ISOLATING ENGINEERED SURFACE FEATURES”. The entire contents of both priority documents are incorporated by reference herein.

### TECHNICAL FIELD

The invention relates to components for combustion turbine engines, with ceramic matrix composite (“CMC”) structures that are in turn insulated by a thermal barrier coating (“TBC”), and methods for making such components. More particularly, the invention relates to engine components for combustion turbines, with ceramic matrix composite (“CMC”) structures, having engineered surface features (“ESFs”) that anchor the TBC.

### BACKGROUND

CMC structures comprise a solidified ceramic core, in which is embedded a three-dimensional matrix or other array of ceramic fibers. The embedded ceramic fibers within the ceramic core of the CMC improve elongation rupture resistance, fracture toughness, thermal shock resistance, and dynamic load capabilities, compared to ceramic structures that do not incorporate the embedded fibers. The CMC embedded fiber orientation also facilitates selective anisotropic alteration of the component's structural properties. CMC structures are fabricated by orienting ceramic fibers, also known as “rovings”, into fabrics, filament windings, or braids that comprise a three-dimensional preform. Preform fabrication for CMCs is comparable to what is done to form fiber-reinforced polymer structural components for aircraft wings or boat hulls. The preform is impregnated with ceramic material by such techniques as gas deposition, melt infiltration, preceramic polymer pyrolysis, chemical reactions, sintering, or electrophoretic deposition of ceramic powders, creating a solid ceramic structure with embedded, oriented ceramic fibers.

Ceramic matrix composite (“CMC”) structures are being incorporated into gas turbine engine components as insulation layers and/or structural elements of such components, such as insulating sleeves, vanes and turbine blades. These CMCs provide better oxidation resistance, and higher temperature capability, in the range of approximately 1150 degrees Celsius (“C.”) for oxide based ceramic matrix composites, and up to around 1350 C. for Silicon Carbide fiber—Silicon Carbide core (“SiC—SiC”) based ceramic matrix composites, whereas nickel or cobalt based superalloys are generally limited to approximately 950 to 1000 degrees Celsius under similar operating conditions within engines. While 1150 C. (1350 C for SiC—SiC based CMCs) operating capability is an improvement over traditional superalloy temperature limits, mechanical strength (e.g., load bearing capacity) of CMCs is also limited by grain growth and reaction processes with the matrix and/or the environment at 1150 C./1350 C. and higher. With desired combustion turbine engine firing temperatures as high as 1600-1700 C., the CMCs need additional thermal insulation protection interposed between themselves and the combustion gasses, to maintain their temperature below 1150 C./1350 C.

CMCs are receiving additional thermal insulation protection by application of overlayer(s) of thermal barrier coats or coatings (“TBCs”), as has been done in the past with superalloy components. However, TBC application over CMC or superalloy substrates presents new and different thermal expansion mismatch and adhesion challenges. During gas turbine engine operation superalloy, CMC and TBC materials all have different thermal expansion properties. In the case of TBC application over superalloy substrates, the superalloy material expands more than the overlying TBC material, which in extreme cases leads to crack formation in the TBC layer and its delamination from the superalloy surface. Along with thermal mismatch challenges, metallic substrate/TBC interfaces have adhesion challenges. While TBC material generally adheres well to a fresh metallic superalloy substrate, or in an overlying metallic bond coat (“BC”) substrate, the metals generate oxide surface layers, which subsequently degrade adhesion to the TBC at the respective layer interface.

TBC/metallic substrate interface integrity is maintained by use of the inventions in the incorporated by reference in the priority International Application No. PCT/US15/16318, entitled “TURBINE COMPONENT THERMAL BARRIER COATING WITH CRACK ISOLATING ENGINEERED GROOVE FEATURES”; and International Application No. PCT/US15/16331, entitled “TURBINE COMPONENT THERMAL BARRIER COATING WITH CRACK ISOLATING ENGINEERED SURFACE FEATURES”. Some embodiments described in the priority applications incorporate engineered surface features (“ESFs”) on the substrate surface of the metallic superalloy substrate, or in an overlying metallic bond coat (“BC”), or a combination in both metallic surfaces. The ESFs at the metal surface/TBC layer interface mechanically anchor the TBC material, to inhibit delamination or at least confine delamination damage to boundaries defined by adjacent ESFs. Other embodiments in the priority applications incorporate engineered groove features (“EGFs”) on the TBC layer outer surface, to control surface crack propagation. Additional embodiments in those applications incorporate both ESFs and EGFs. Therefore, as the metal material is heated (forming surface oxides) and expands during engine operation, the lesser expanding TBC material is mechanically interlocked with the metal, despite degradation of interlayer adhesion.

Turning back to CMC/TBC thermal expansion mismatch and general interlayer adhesion challenges, relative layer expansion is opposite that experienced by superalloy/TBC components. The TBC material tends to expand more than underlying CMC material. As the TBC heats, it tends to lose adhesion with and delaminate from the CMC surface. Many CMC materials already contain oxides in the solidified ceramic core and in their embedded ceramic fibers, which adversely affect inter-layer adhesion at the CMC/TBC interface. In the case of SiC—SiC composites, the thermal barrier coatings can react with the underlying Silicon based matrix to form new chemical compounds, more brittle than the matrix or coating. Therefore, application of the TBC on the CMC surface of the component without subsequent delamination during engine operation is difficult. Depending upon the local macro roughness of the embedded ceramic fibers in the preform, and the infiltration characteristics of the ceramic material, which embed the preform into the solidified ceramic core, the adhesion of TBC coatings, is generally poorer than that of TBC coating on metallic substrates. TBC/CMC adhesion is particularly poor where the preform embedded fibers are oriented parallel to the component surface. TBC layer thickness is limited to that which will maintain adhesion to the CMC surface, despite its higher rate of thermal expansion. In other words, TBC layer thickness is kept below a threshold that accelerates the TBC/CMC thermal expansion delamination, within the already relatively limited bounds of TBC/CMC material adhesion capabilities. Unfortunately, limiting the TBC layer thickness undesirably limits its insulation properties. Generally, a thicker TBC layer offers more insulation protection to the underlying CMC substrate/layer than a thinner layer.

### SUMMARY OF INVENTION

Exemplary embodiments described herein enhance TBC retention on CMC components in combustion turbine engines, by cutting engineered surface features (“ESFs”) within the surface of the CMC ceramic core and the embedded ceramic fibers. The ESFs mechanically interlock the CMC structure, and in particular the fibers bundles, to the TBC, and provide increased surface area and additional interlocking for interlayer adhesion. A thermally sprayed or vapor deposited or solution/suspension plasma sprayed TBC is applied over and coupled to the ceramic core outer surface and the ESFs. Increased adherence capabilities afforded by the ESFs facilitate application of thicker TBC layers to the component, which increases insulation protection for the underlying CMC structure/layer. The increased adhesion surface area and added mechanical interlocking of the respective materials facilitates application of greater TBC layer thickness to the CMC substrate without risk of TBC delamination. The greater TBC layer thickness in turn provides more thermal insulation to the CMC structure, for higher potential engine operating temperatures and efficiency. In some embodiments, the CMC component covers an underlying substrate, such as a superalloy metallic substrate. In other embodiments, the CMC component is a sleeve over a metallic substrate. In other embodiments, the CMC component has no underlying metallic substrate, and provides its own internal structural support. In additional embodiments, a plurality of CMC components are joined together to form a larger, composite CMC component, such as a laminated turbine blade or vane.

In some embodiments, engineered groove features (“EGFs”) are applied to the TBC outer surface. In some embodiments, a plurality of stacked, laterally adjoining respective CMC cores cover the substrate surface, with each respective core having embedded ceramic preforms and ESFs on the core surface; after which is applied a contiguous, uninterrupted TBC over all of the core outer surfaces and ESFs. In other embodiments, the CMC ceramic core, or plurality of adjoining, stacked ceramic cores are an independent sleeve that is applied over a substrate surface, such as a metallic substrate. In some embodiments, the respective stacked ceramic cores have differing surface profiles, which collectively form ESFs. In other embodiments, the respective stacked cores define a pattern of higher and lower surface heights, which collectively form ESFs.

The CMC component is made by fabricating with ceramic fibers a three-dimensional preform, and infiltrating the preform fibers with ceramic material, forming a solidified ceramic core. The ESFs are cut into the core outer surface and fibers of the preform. The TBC is then applied to the core outer surface and the ESFs.

Exemplary embodiments of the invention feature a ceramic matrix composite (“CMC”) component for a combustion turbine engine has a solidified ceramic core, with a three-dimensional preform of ceramic fibers, embedded therein. Engineered surface features (“ESFs”) cut into an outer surface of the core and fibers of the preform. A thermally sprayed, or vapor deposited, or solution/suspension plasma sprayed thermal barrier coat (“TBC”) is applied over and coupled to the core outer surface and the ESFs. The ESFs provide increased surface area and mechanically interlock the TBC, improving adhesion between the ceramic core and the TBC.

Other exemplary embodiments of the invention feature a component for a combustion turbine engine, which component includes a substrate, having a substrate surface, which defines a surface profile. A ceramic matrix composite (“CMC”) layer covers the substrate. In some embodiments, the CMC layer also functions as a substrate. The CMC layer includes solidified ceramic core, with a ceramic core inner surface that is shaped to conform to and abut the substrate surface profile. Ceramic fibers are formed into a three-dimensional preform that is shaped to conform to the substrate surface profile. The preform is embedded within solidified ceramic core. Engineered surface features (“ESFs”) are cut into the ceramic core outer surface and fibers of the preform. A thermally sprayed or vapor deposited or solution/suspension plasma sprayed thermal barrier coat (“TBC”), including a TBC inner surface, is applied over and coupled to the core outer surface and the ESFs. The TBC outer surface is exposed to combustion gas during engine operation. It insulates the underlying CMC layer and the substrate.

Other exemplary embodiments of the invention feature methods for manufacturing a combustion turbine component. A three-dimensional preform is fabricated with ceramic fibers. The fibers of the preform are infiltrated with ceramic material, forming a solidified ceramic core, which defines a core outer surface. Engineered surface features (“ESFs”) are formed, by cutting into the core outer surface and fibers of the preform. A thermally sprayed, or vapor deposited, or solution/suspension plasma sprayed thermal barrier coat (“TBC”) is applied over and coupled to the core outer surface and the ESFs. In some embodiments, a substrate is provided, which has a substrate surface defining a surface profile. The substrate surface is covered with a ceramic matrix composite (“CMC”) layer.

The respective features of the exemplary embodiments of the invention that are described herein may be applied jointly or severally in any combination or sub-combination.

### BRIEF DESCRIPTION OF DRAWINGS

The exemplary embodiments of the invention are further described in the following detailed description in conjunction with the accompanying drawings, in which:

FIG. 1 is a partial axial cross sectional view of a gas or combustion turbine engine, incorporating one or more CMC components constructed in accordance with exemplary embodiments of the invention;

FIG. 2 is a cross sectional schematic view of a CMC component for a combustion turbine engine, in accordance with an exemplary embodiment of the invention;

FIG. 3 is a photograph of a solidified ceramic core of a CMC component, with raised dimple-shaped engineered surface features (“ESFs”) cut into the core outer surface and ceramic fibers of the embedded preform, prior to application of a TBC, in accordance with an embodiment of the invention;

FIG. 4 is a photograph of the ceramic core of FIG. 3, after application of a TBC over the core outer surface and the ESFs, in accordance with an embodiment of the invention;

FIG. 5 is a cross sectional schematic view of a CMC component for a combustion turbine engine, having a plurality of stacked, laterally adjoining respective ceramic cores of different height forming ESFs, in accordance with another exemplary embodiment of the invention;

FIG. 6 is a photograph of a ring-shaped, solidified ceramic core of a sleeve-like CMC component, with raised rib-shaped engineered surface features (“ESFs”) cut into the core outer circumferential surface and ceramic fibers of the embedded preform, prior to application of a TBC, in accordance with another embodiment of the invention;

FIG. 7 is a photograph of three ceramic core sleeves, each sleeve respectively formed from a plurality of five stacked, laterally adjoining respective ring-shaped ceramic cores of FIG. 6, prior to application of a TBC, in accordance with an embodiment of the invention;

FIG. 8 is a photograph of one of the sleeves of FIG. 7, after application of the TBC, in accordance with an embodiment of the invention; and

FIG. 9 is a photograph of the sleeve of FIG. 8, after formation of engineered groove features (“EGFs”) on the outer surface of the TBC.

To facilitate understanding, identical reference numerals have been used, where possible, to designate identical elements that are common to the figures. The figures are not drawn to scale.

### DESCRIPTION OF EMBODIMENTS

Exemplary embodiments of the invention are utilized in combustion turbine engines. In some embodiments, the ceramic matrix composite (“CMC”) components of the invention are utilized as insulative covers or sleeves for other structural components, such as metallic superalloy components. In other embodiments, the CMC component is structurally self-supporting. Embodiments of the CMC components of the invention are combined to form composite structures, such as turbine blades or vanes, which are structurally self-supporting or which cover other structural elements. Embodiments of the CMC components of the invention have a solidified ceramic core, with a three-dimensional preform of ceramic fibers, embedded therein. Engineered surface features (“ESFs”) cut into an outer surface of the core and fibers of the preform. A thermally sprayed, or vapor deposited, or solution/suspension plasma sprayed thermal barrier coat (“TBC”) is applied over and coupled to the core outer surface and the ESFs. In some embodiments, engineered groove features (“EGFs”) are cut into the TBC outer surface.

The ESFs of the invention provide increased surface area and mechanically interlock the TBC, improving adhesion between the ceramic core and the TBC. The mechanical interlocking and improved adhesion afforded by the ESFs facilitate application of relatively thick TBC layers, from 0.5 mm to 2.0 mm. Because of the thick TBC application, embodiments of the CMC components of the invention are capable of operation in combustion environments up to 1950 degrees Celsius, with the thick TBC limiting the CMC ceramic core temperature to below 1150/1350 degrees Celsius.

In accordance with method embodiments of the invention, the CMC component is made by fabricating with ceramic fibers a three-dimensional preform, and infiltrating the preform fibers with ceramic material, forming a solidified ceramic core. The ESFS are cut into the core outer surface and fibers of the preform. The TBC is then applied to the core outer surface and the ESFs. If the CMC component is structurally self-supporting, the TBC layered core is configured by machining or other manufacturing means to its final dimensions. If the CMC component is an insulative cover for another structural component, such as a superalloy substrate, the component is dimensioned to cover the substrate. In some applications the CMC component, or a plurality of CMC components are configured as insulative sleeves to cover the substrate component. In some embodiments, a plurality of such sleeves are stacked and laterally joined over a substrate, prior to TBC application.

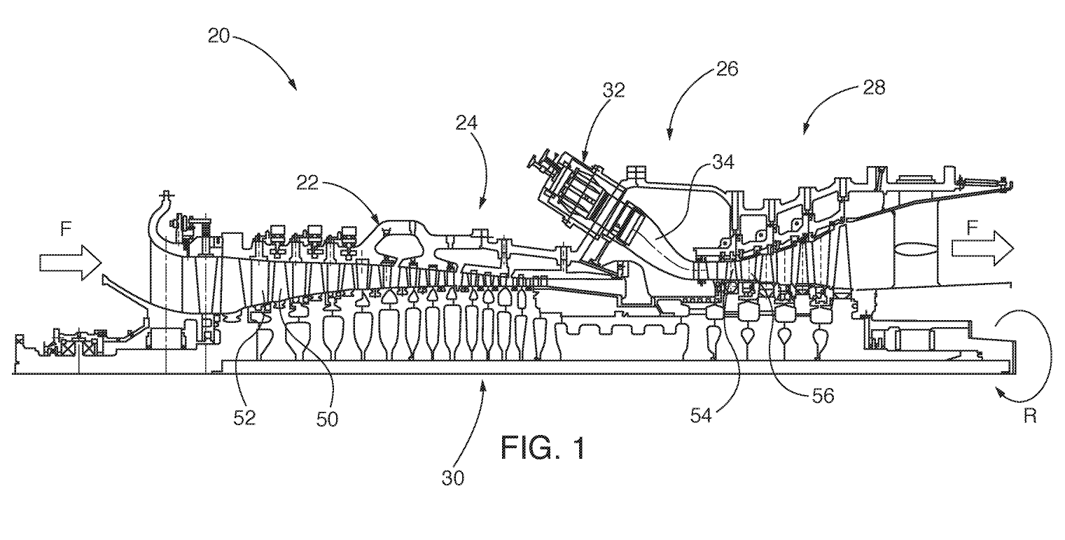

FIG. 1 shows a gas turbine engine 20, having a gas turbine casing 22, a multi-stage compressor section 24, a combustion section 26, a multi-stage turbine section 28 and a rotor 30. One of a plurality of basket-type combustors 32 is coupled to a downstream transition 34 that directs combustion gasses from the combustor to the turbine section 28. Atmospheric pressure intake air is drawn into the compressor section 24 generally in the direction of the flow arrows F along the axial length of the turbine engine 20. The intake air is progressively pressurized in the compressor section 24 by rows rotating compressor blades 50 and directed by mating compressor vanes 52 to the combustion section 26, where it is mixed with fuel and ignited. The ignited fuel/air mixture, now under greater pressure and velocity than the original intake air, is directed through a transition 34 to the sequential vane 56 and blade 50 rows in the turbine section 28. The engine's rotor 30 and shaft retains the plurality of rows of airfoil cross sectional shaped turbine blades 54. Embodiments of the CMC components described herein are designed to operate in engine temperature environments of up to 1950 degrees Celsius. In some embodiments, the CMC components are insulative sleeves or coverings for metallic substrate structural components, such as the subcomponents within the combustors 32, the transitions 34, the blades 54 or the vanes 56. In other embodiments, the CMC components of the invention are structurally self-supporting, without the need for metallic substrates. Exemplary self-supporting CMC components include compressor blades 50 or vanes 52 (which do not necessarily require the insulation of a TBC, internal subcomponents of combustors 32 or transitions 34). In some embodiments, entire turbine section 28 blades 54 or vane 56 airfoils are CMC structures; with their fiber preform embedded ceramic cores having ESFs that mechanically interlock a relatively thick TBC layer of 0.5 to 2.0 mm.

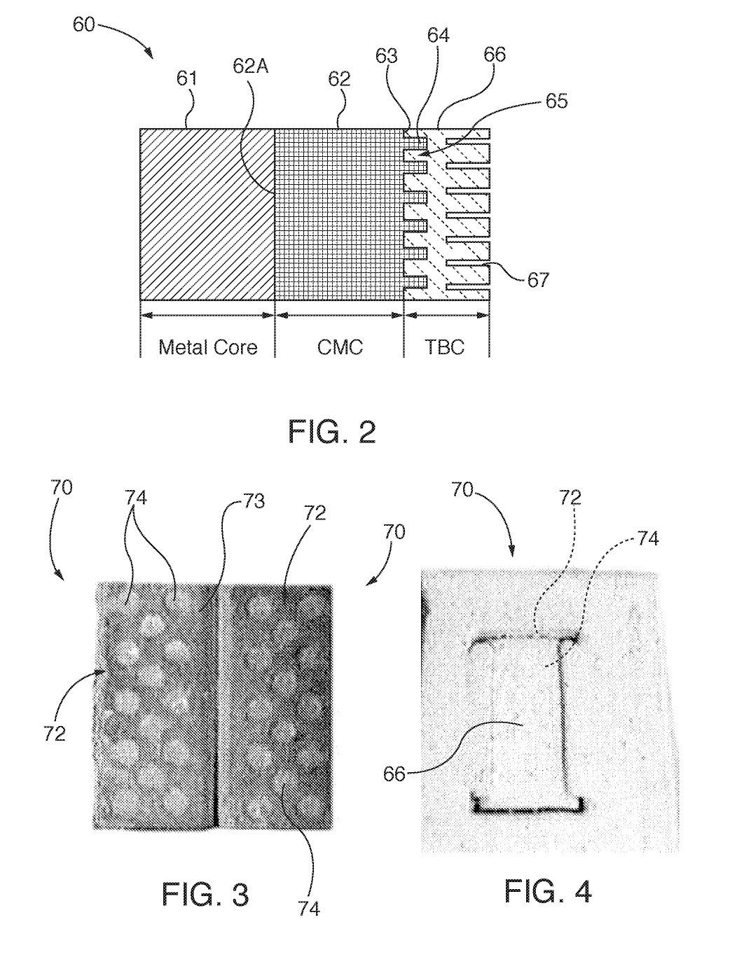

A schematic cross section of an exemplary engine component 60 is shown in FIG. 2. The engine component 60 comprises a metallic core substrate 61, which is covered by a CMC ceramic core 62, having a preform matrix of ceramic fibers 62A, embedded therein. The core 62 outer surface 63 has an array of a plurality of engineered surface features (“ESFs”) 64 projecting therefrom, which were cut in into the core outer surface 63 and the preform 62A ceramic fibers, defining gaps 65 between the ESFs. While rectangular cross sections ESFs 64 are shown, any other shape can be substituted, such as cylindrical, triangular, trapezoidal, or intersecting grid patterns. Exemplary ESFs 64 have a height of between 0.1 mm and 1.5 mm, and a centerline-to-centerline pitch spacing density between 0.1 mm and 8 mm.

A thermally sprayed or vapor deposited or solution/suspension plasma sprayed thermal barrier coat (“TBC”) 66 is applied over and coupled to the core outer surface and the ESFs. The TBC 66 bonds to the ceramic core 62, with the ESFs 64 increasing surface area along the bonding zone, compared to a flat planar bonding zone. The ESFs 64 also provide mechanical interlocking of the ceramic core 62 and the TBC 66. Experience has shown that TBC tends to delaminate and spall from a flat CMC outer surface, especially if the preform 62A fibers are oriented parallel to the ceramic core outer surface. In embodiments of the invention, the cut ESFs 64 also cut fibers within the preform 62A. In the ESF zone, the preform 62A fibers are skewed or perpendicular to the TBC layer along lateral sides of the ESFs within the gap 65, which creates abutting interfaces, rather than parallel interfaces in comparable flat surfaces formed without the ESFs. TBC 66 adhesion to the CMC ceramic core 62 is enhanced by bonding between the TBC material and the cut fiber ends. Cutting ceramic fibers in outer peripheral zones, not intended for bearing structural load, of the preform 62A does not impair structural integrity of the CMC component. The outer peripheral zones are primarily intended for adhesion of the TBC.

Optional engineered groove features (“EGFs”) 67 are cut into the TBC outer surface, as described in the incorporated by reference priority International Application No. PCT/US15/16318, entitled “TURBINE COMPONENT THERMAL BARRIER COATING WITH CRACK ISOLATING ENGINEERED GROOVE FEATURES”; and International Application No. PCT/US15/16331, entitled “TURBINE COMPONENT THERMAL BARRIER COATING WITH CRACK ISOLATING ENGINEERED SURFACE FEATURES”. In some embodiments, as described in the priority documents, the EGFs 67 are cut in pattern arrays, including pattern arrays that intersect the ESFs 64 of the CMC ceramic core 62, for enhanced spallation isolation.

FIG. 3 is a photograph of a pair of laterally aligned CMC components 70, with their respective core 72 outer surfaces and embedded preform ceramic fibers cut by milling arrays of dimple- or cylindrical-shaped ESFs 74. FIG. 4 shows one of the components 70 after application of a TBC 66 over its ceramic core 72 and the ESFs 74.

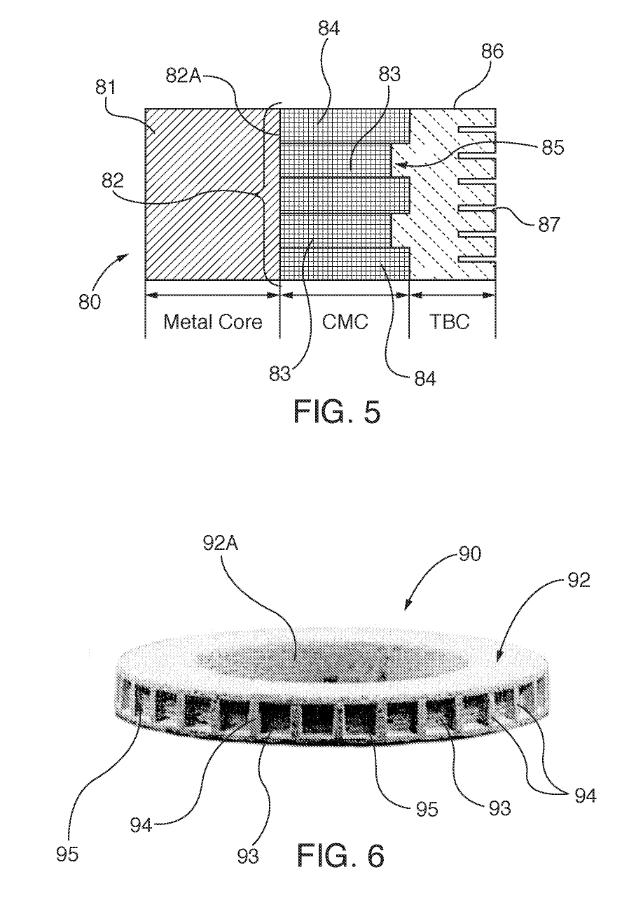

In the embodiment of FIG. 5, the CMC component 80 comprises a metallic core 81 that is covered by a plurality of stacked, laterally adjoining respective ceramic cores 83 and 84, each core has therein its own embedded ceramic-fiber preform. The several embedded preforms are designated, jointly and collectively, by the reference number 84 in FIG. 5. Fibers of the preforms are exposed on all surfaces that abut the contiguous, uninterrupted TBC 86. In this embodiment, the outward faces of the ceramic cores 83 which abut the TBC 86 are shorter than those of the ceramic cores 84. Collectively, the pattern of the alternating height cores 83 and 84, create ESFs that define gaps 85, for mechanically interlocking the TBC 86 and for creating a greater adhesion surface area therebetween. Other profile ESFs are optionally formed by selectively varying the ceramic core outer profiles, symmetrically or asymmetrically. Additional ESFs are optionally formed on exposed surfaces of the ceramic cores 83 and 84, such as the ESFs 94 of the CMC core 92 of FIG. 6. The TBC 86 includes EGFs 87. In the CMC component 80, the plurality of alternating ceramic cores 83 and 84 are collectively a sleeve that circumscribes the metallic core 81. In some embodiments, the TBC 86 is applied as a contiguous, uninterrupted layer over the ceramic cores 83 and 84, after the latter are applied over the metallic core 81. In other embodiments, the TBC 86 is applied over the cores 83 and 84 and the completed sleeve is then applied as an integrated structure over the metallic core 81.

FIG. 6 is a photograph of a CMC component 90 ceramic core 92, prior to application of a TBC. The ceramic core 92 is ring-shaped, having an inner circumference 92A, which is to be slid over a metallic core as part of an insulating sleeve structure with other similar ring-shaped components 90. The ceramic core 92 has an outer circumferential edge 93, into which are formed axially aligned ESFs 94 that are cut into the solidified ceramic material and it preform' s embedded fibers.

Three separate, stacked, CMC sleeves 100 are shown. Each sleeve 100 comprises five separate, axially aligned, ring-shaped ceramic cores 102, each with embedded ceramic fiber preforms. Dimple-shaped ESFs 104 are cut into each ceramic core circumferential edge of the CMC sleeve 100, similar to the structure of the ceramic core 92 of FIG. 6.

In FIG. 8, one of the CMC sleeves 100 is shown after application of a contiguous, uninterrupted TBC 106 that covers each of the respective, equal height, ceramic cores 102 and its associated ESFs 104. In FIG. 9, EGFs 107 are cut into the outer surface of the TBC. The completed CMC sleeve 100 defines an internal circumferential surface 102A, which mates in sliding fashion over a substrate (not shown), insulating the substrate from hot combustion gasses in a turbine engine component.

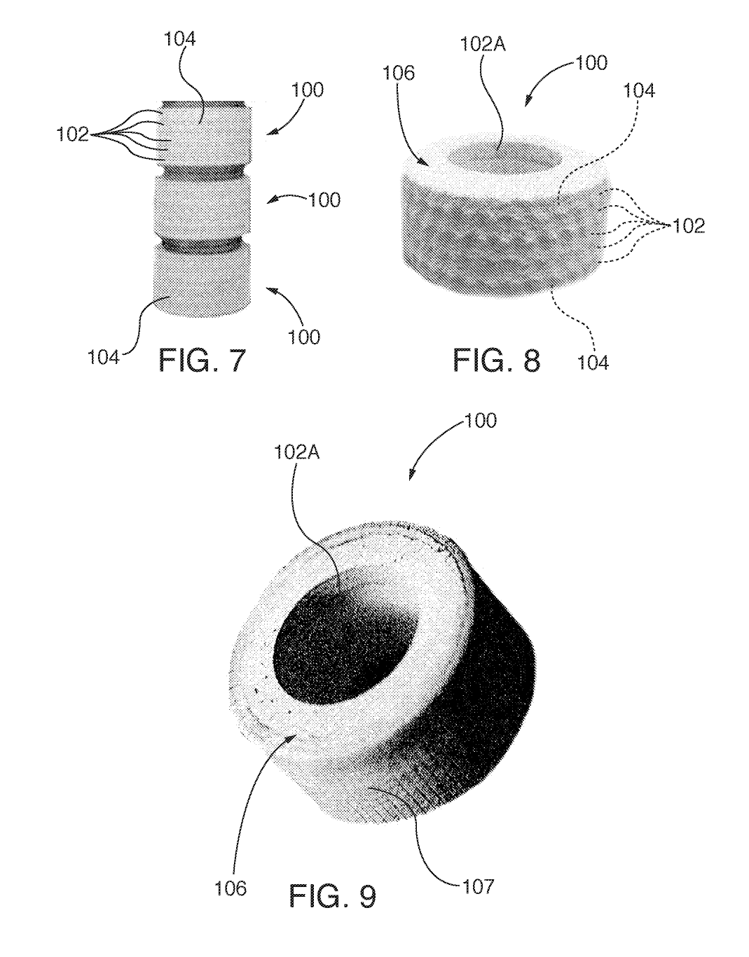

An exemplary method for manufacturing a ceramic matrix composite (“CMC”) component for a combustion turbine engine, such as the oxide fiber-oxide ceramic core CMC components 70, 90 and 100 of FIGS. 3, 4, and 6-9, is now described. A three-dimensional preform, using any known technique, is fabricated with ceramic fibers. Exemplary preforms are formed by weaving ceramic fibers into symmetrical or asymmetrical preform matrices. In some embodiments, the weaving pattern is selectively varied to provide anisotropic structural properties, for example if the finished CMC component is to function as a self-supporting or partially self-supporting structural element, as opposed to a non-structural insulative cover over a metallic or other substrate. The preform' s three-dimensional surface texture can be selectively varied during the weaving process, such as by fabricating graded weave/tow matrices, to alter fiber orientation and anisotropic structural strength, for future bonding with an applied TBC. For example, the preform weave profile can be varied to accommodate future cut ESF orientation between fiber bundles or outwardly jutting projections in the preform. Exemplary fiber materials to form the preform include: silicon carbide, (commercially available under trademarks SYLRAMIC, HI-NICALON, TYRANO), silicon carbon nitride, silicon polyborosilazan, alumina, mullite, alumina-boria-silica (commercially available under trademarks NEXTEL 312, NEXTEL 610, NEXTEL 720, yttrium aluminum garnet (“YAG”), zirconia toughened alumina (“ZTA”), or zirconium oxide (“ZrO₂”). The CMC components 70, 90 and 100 have basket-weave pattern preforms, constructed of alumina or silicon carbide fibers.

After the preform is fabricated, its ceramic fibers are infiltrated ceramic material, to form a solidified ceramic core. Exemplary ceramic materials to impregnate the preform include alumina silicate, alumina zirconia, alumina, yttria stabilized zirconia, silicon, or silicon carbide polymer precursors. The infiltration is performed, by any known technique, including gas deposition, melt infiltration, chemical vapor infiltration, slurry infiltration, preceramic polymer pyrolysis, chemical reactions, sintering, or electrophoretic deposition of ceramic powders, creating a solid ceramic structure with embedded, oriented ceramic fibers. In the case of oxide ceramic matrix composites, the solidified ceramic core incorporates the preform. The solidified ceramic cores 72, 92 and 102 of FIGS. 3, 4 and 6-9 are impregnated with slurry of alumina silicate or alumina zirconia ceramic oxide material. The slurry impregnated preform is then fired to harden the slurry, using known ceramic production techniques, forming the solidified ceramic core. In some embodiments, flexible ceramic pre-pregs are used to form the solidified ceramic core.

Engineered surface features (“ESFs”) are cut into the core outer surface and into fibers of the preform, with any known cutting technique, including mechanical machining, ablation by laser or electric discharge machining, grid blasting, or high pressure fluid. While general CMC fabrication generally disfavors cutting fibers within a preform, for fear of structural weakening, cutting fibers proximate the ceramic core surface, such as in the CMC components of FIGS. 3, 4, and 6-9, has not structurally weakened those components. The ESFs 74 of FIGS. 3 and 4 are mechanically cut by milling the ceramic core 72, while the ESFs of FIGS. 6-9 are cut by laser ablation.

A known composition, thermally sprayed, or vapor deposited, or solution/suspension plasma sprayed thermal barrier coat (“TBC”) is applied over the ceramic core. Exemplary TBC compositions include single layers of 8 weight percent yttria stabilized zirconia (“8YSZ”), or 20 weight percent yttria stabilized zirconia (“20YSZ”). For pyrochlore containing thermal barrier coatings, an underlayer of 8YSZ is required to form a bilayer 8YSZ/59 weight percent gadolinium stabilized zirconia (8YSZ/59GZO) coating, or a bilayer 8YSZ/30-50 weight percent yttria stabilized zirconia (“30-50 YSZ”) coating, or combinations thereof. The TBC adheres to the ceramic core outer surface, including the ESFs. The ESFs increase surface area for TBC to ceramic core adhesion, and provide mechanical interlocking of the materials. Cut ceramic fiber ends along sides of the ESFs adhere to and abut the TBC material, further increasing adhesion strength. Optionally, a rough surface ceramic bond coat is applied over the ESFs by a known deposition process, further enhancing adhesion of the TBC layer to the ceramic core. In exemplary embodiments, the bond coat material is alumina or YAG to enable oxidation protection, in case of complete TBC spallation.

Increased ceramic core/TBC adhesion, attributable to increased adhesion surface area, mechanical interlocking, and exposed ceramic fiber/TBC adhesion facilitate application of thicker TBC layers in the range of 0.5 mm to 2.00 mm, which would otherwise potentially delaminate from a comparable flat surface TBC/ceramic core interface. Thicker TBC increases insulation protection to the underlying CMC ceramic core and fibers. Exemplary simulated turbine component structures fabricated in accordance with embodiments described herein withstand TBC outer layer exposure to 1950 degrees Celsius combustion temperatures, while maintaining the underlying CMC ceramic core and fiber temperatures below 1150 degrees/1350 degrees Celsius. As previously noted CMC core and fiber exposure to temperatures above 1150 C./1350 C. thermally degrade those structures.

Although various embodiments that incorporate the invention have been shown and described in detail herein, others can readily devise many other varied embodiments that still incorporate the claimed invention. The invention is not limited in its application to the exemplary embodiment details of construction and the arrangement of components set forth in the description or illustrated in the drawings. The invention is capable of other embodiments and of being practiced or of being carried out in various ways. In addition, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted”, “connected”, “supported”, and “coupled”, and variations thereof are used broadly and encompass direct and indirect mountings, connections, supports, and couplings. Further, “connected” and “coupled” are not restricted to physical, mechanical, or electrical connections or couplings.

1. A ceramic matrix composite (“CMC”) component for a combustion turbine engine comprising:
a solidified ceramic core having a three-dimensional preform of ceramic fibers embedded therein, and a core outer surface;
engineered surface features (“ESFs”) cut into the core outer surface and fibers of the preform; and
a thermal barrier coat (“TBC”), including a TBC inner surface applied over and coupled to the core outer surface and the ESFs, and a TBC outer surface for exposure to combustion gas.

2. The engine component of claim 1, the TBC outer surface having engineered groove features (“EGFs”).

3. The engine component of claim 1, further comprising:
a plurality of stacked, laterally adjoining respective ceramic cores, with embedded ceramic-fiber preforms and ESFs on core outer surfaces thereof, covering a substrate surface; and
a contiguous, uninterrupted TBC covering the plurality of respective core outer surfaces and their ESFs.

4. The engine component of claim 3, the respective stacked ceramic cores having differing outer surface profiles, which collectively form the ESFs.

5. The engine component of claim 4, the respective stacked ceramic cores defining a pattern of higher and lower surface heights, which collectively form ESFs.

6. The engine component of claim 1, wherein the TBC thickness is between 0.5 to 2 mm.

7. The engine component of claim 1, the ESFs having a height of between approximately 0.1 to 1.5 mm with a spacing of 0.1 to 8 mm.

8. The engine component of claim 1, wherein the ceramic core is in a form of a sleeve that is applied over a separate substrate surface.

9. The engine component of claim 8, further comprising:
a plurality of stacked, laterally adjoining respective sleeves, with embedded ceramic-fiber preforms and ESFs on core outer surfaces thereof, covering the substrate surface; and
a contiguous, uninterrupted TBC, covering the plurality of respective core outer surfaces and their ESFs.

10. The engine component of claim 1, the ceramic fibers comprising silicon carbide, silicon carbon nitride, silicon polyborosilazan, alumina, mullite, alumina-boria-silica, yttrium aluminum garnet, zirconia toughened alumina, or zirconium oxide.

11. The engine component of claim 1, the ceramic core comprising alumina, alumina-zirconia, alumina-silica, silicon carbide, yttria stabilized zirconia, silicon, or silicon carbide polymer precursors.

12. A method for manufacturing a ceramic matrix composite (“CMC”) component for a combustion turbine engine, comprising:
fabricating, with ceramic fibers, a three-dimensional preform;
infiltrating the fibers of the preform with ceramic material, forming a solidified ceramic core, which defines a core outer surface;
forming engineered surface features (“ESFs”) that are cut into the core outer surface and fibers of the preform; and
applying a thermal barrier coat (“TBC”) over and coupled to the core outer surface and the ESFs.

13. The method of claim 12, further comprising forming engineered groove features (“EGFs”) on the TBC outer surface.

14. The method of claim 9, wherein the ESFs have a height of between 0.1 to 1.5 mm and a spacing of between 0.1 mm to 8 mm.

15. The method of claim 12, wherein the applied TBC layer thickness is between 0.5 to 2 mm.

16. The method of claim 12, wherein the solidified ceramic core is in the form of a sleeve that is applied over a separate substrate surface.

17. The method of claim 16, further comprising:
fabricating a plurality of sleeves;
covering the substrate surface with a stack of laterally adjoining respective sleeves; and
applying a contiguous, uninterrupted TBC, covering the plurality of respective core outer surfaces and their ESFs.

18. The method of claim 17, further comprising stacking sleeves having differing outer surface profiles, which collectively form the ESFs between adjacent sleeves.

19. The method of claim 12, further comprising:
providing a substrate having a substrate surface;
fabricating a plurality of ceramic cores, with embedded ceramic-fiber preforms and ESFs on core outer surfaces thereof;
covering the substrate surface with said plurality of ceramic cores, by stacking said cores in a laterally adjoining fashion; and
applying a contiguous, uninterrupted TBC covering the plurality of respective core outer surfaces and their ESFs.

20. The method of claim 12, further comprising applying a ceramic bond coat to the outer surface of the ceramic core, after formation of the ESFs and prior to application of the TBC.
